(19) United States
(12) Patent Application Publication
(10) Pub. No.: US 2024/0120280 A1
(43) Pub. Date: Apr. 11, 2024

(54) SEMICONDUCTOR PACKAGE

(71) Applicant: Samsung Electronics Co., Ltd., Suwon-si (KR)

(72) Inventors: Kyungdon Mun, Suwon-si (KR); Shanghoon Seo, Suwon-si (KR); Jihwang Kim, Suwon-si (KR); Sangjin Baek, Suwon-si (KR); Hyeonjeong Hwang, Suwon-si (KR)

(73) Assignee: Samsung Electronics Co., Ltd., Suwon-si (KR)

(21) Appl. No.: 18/214,341

(22) Filed: Jun. 26, 2023

(30) Foreign Application Priority Data
Oct. 6, 2022 (KR) 10-2022-0128084

(51) Int. Cl. H01L 23/538; H01L 21/56; H01L 23/00; H01L 25/00; H01L 25/16; H01L 25/18; H10B 80/00

(52) U.S. Cl. CPC H01L 23/5383; H01L 21/561; H01L 23/5385; H01L 23/5386; H01L 23/5389; H01L 24/05; H01L 24/16; H01L 25/16; H01L 25/18; H01L 25/50; H10B 80/00; H01L 24/06; H01L 24/17; H01L 24/32; H01L 24/33; H01L 24/73; H01L 2224/05624; H01L 2224/05647; H01L 2224/0603; H01L 2224/06181; H01L 2224/16145; H01L 2224/16227; H01L 2224/17181; H01L 2224/32145; H01L 2224/32225; H01L 2224/32245; H01L 2224/33181; H01L 2224/73204; H01L 2224/73253; H01L 2924/1431; H01L 2924/1432; H01L 2924/1433; H01L 2924/1436; H01L 2924/1437; H01L 2924/1443; H01L 2924/14511; H01L 2924/19106

(57) ABSTRACT

A semiconductor package includes a first redistribution structure, a first semiconductor device mounted on the first redistribution structure, a molding layer surrounding the first semiconductor device, a second redistribution structure disposed on the molding layer and the first semiconductor device, a plurality of vertical connection conductors vertically extending in the molding layer and electrically connecting the first redistribution pattern to the second redistribution pattern, a second semiconductor device mounted on the second redistribution structure, the second semiconductor device and the first semiconductor device vertically and partially overlapping each other, a heat dissipation pad structure contacting an upper surface of the first semiconductor device, and a heat dissipation plate disposed on the heat dissipation pad structure and spaced apart from the second semiconductor device along a first straight line extending in a horizontal direction that is parallel to the upper surface of the first semiconductor device.

### CROSS-REFERENCE TO RELATED APPLICATION

This application is based on and claims priority under 35 U.S.C. § 119 to Korean Patent Application No. 10-2022-0128084, filed on Oct. 6, 2022, in the Korean Intellectual Property Office, the disclosure of which is incorporated by reference herein in its entirety.

### BACKGROUND

The inventive concept relates to a semiconductor package.

According to the rapid development of the electronics industry and user demands, electronic devices are being miniaturized, multi-functional, and made to have large capacity. Accordingly, a semiconductor package including a plurality of semiconductor chips is desirable. For example, a method of mounting several types of semiconductor chips side-by-side on one package substrate or stacking semiconductor chips and/or packages on one package substrate may be used.

### SUMMARY

The inventive concept provides a semiconductor package including a plurality of semiconductor devices.

According to an aspect of the inventive concept, a semiconductor package includes a first redistribution structure including a first redistribution insulating layer and a first redistribution pattern, a first semiconductor device mounted on the first redistribution structure, a molding layer surrounding the first semiconductor device on the first redistribution structure, a second redistribution structure disposed on the molding layer and the first semiconductor device and including a second redistribution insulating layer and a second redistribution pattern, a plurality of vertical connection conductors vertically extending in the molding layer and electrically connecting the first redistribution pattern to the second redistribution pattern, a second semiconductor device mounted on the second redistribution structure, wherein the second semiconductor device and the first semiconductor device vertically and partially overlap each other, a heat dissipation pad structure contacting an upper surface of the first semiconductor device, and a heat dissipation plate disposed on the heat dissipation pad structure and spaced apart from the second semiconductor device along a first straight line extending in a horizontal direction that is parallel to the upper surface of the first semiconductor device.

According to an aspect of the inventive concept, a semiconductor package includes a first redistribution structure including a first redistribution insulating layer and a first redistribution pattern, a first semiconductor device mounted on the first redistribution structure, a molding layer surrounding the first semiconductor device on the first redistribution structure without covering an upper surface of the first semiconductor device, a plurality of vertical connection conductors extending vertically in the molding layer and electrically connected to the first redistribution pattern, a second semiconductor device disposed on the molding layer and electrically connected to the first redistribution pattern through the plurality of vertical connection conductors, and a heat dissipation plate attached to the upper surface of the first semiconductor device and adjacent to the second semiconductor device along a first straight line extending in a horizontal direction that is parallel to the upper surface of the first semiconductor device.

According to an aspect of the inventive concept, a semiconductor package includes a first redistribution structure including a first redistribution insulating layer and a first redistribution pattern, a first semiconductor device mounted on the first redistribution structure, a plurality of chip connection bumps disposed between the first semiconductor device and the first redistribution structure, a molding layer surrounding the first semiconductor device on the first redistribution structure and having an upper surface that is coplanar with an upper surface of the first semiconductor device, a second redistribution structure disposed on the molding layer and the first semiconductor device and including a second redistribution insulating layer and a second redistribution pattern, a plurality of vertical connection conductors vertically penetrating the molding layer and electrically connecting the first redistribution pattern to the second redistribution pattern, a second semiconductor device mounted on the second redistribution structure, a heat dissipation pad structure disposed within the second redistribution insulating layer and contacting the upper surface of the first semiconductor device, and a heat dissipation plate disposed on the heat dissipation pad structure and spaced apart from the second semiconductor device along a straight line extending in horizontal direction that is parallel to the upper surface of the first semiconductor device. The first semiconductor device comprises a logic chip. The second semiconductor device comprises a memory chip. The heat dissipation plate is thermally coupled to the first semiconductor device through the heat dissipation pad structure. A first portion of the first semiconductor device vertically overlaps the second semiconductor device. A second portion of the first semiconductor device vertically overlaps the heat dissipation plate. A ratio between a first length of the first portion of the first semiconductor device to a total length of the first semiconductor device is selected from a range between 10% to 45%. The first length and the total length are measured in the horizontal direction.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view illustrating a semiconductor package according to embodiments of the inventive concept;

FIG. 2 is a layout diagram of main components of the semiconductor package of FIG. 1;

FIGS. 3A to 3H are cross-sectional views illustrating a method of manufacturing a semiconductor package according to embodiments of the inventive concept;

FIG. 4 is a cross-sectional view illustrating a semiconductor package according to embodiments of the inventive concept;

FIG. 5 is a cross-sectional view illustrating a semiconductor package according to embodiments of the inventive concept;

FIG. 6 is a cross-sectional view illustrating a semiconductor package according to embodiments of the inventive concept;

FIG. 7 is a cross-sectional view illustrating a semiconductor package according to embodiments of the inventive concept;

FIG. 8 is a cross-sectional view illustrating a semiconductor package according to embodiments of the inventive concept;

FIG. 9 is a cross-sectional view illustrating a semiconductor package according to example embodiments of the inventive concepts;

FIG. 10 is a cross-sectional view illustrating a semiconductor package according to embodiments of the inventive concept;

FIG. 11 is a cross-sectional view illustrating a semiconductor package according to embodiments of the inventive concept;

FIG. 12 is a cross-sectional view illustrating a semiconductor package according to example embodiments of the inventive concepts; and

FIG. 13 is a cross-sectional view illustrating a semiconductor package according to example embodiments of the inventive concepts.

### DETAILED DESCRIPTION OF THE EMBODIMENTS

Hereinafter, embodiments of the technical idea of the inventive concept will be described in detail with reference to the accompanying drawings. The same reference numerals are used for the same components in the drawings, and duplicate descriptions thereof are omitted.

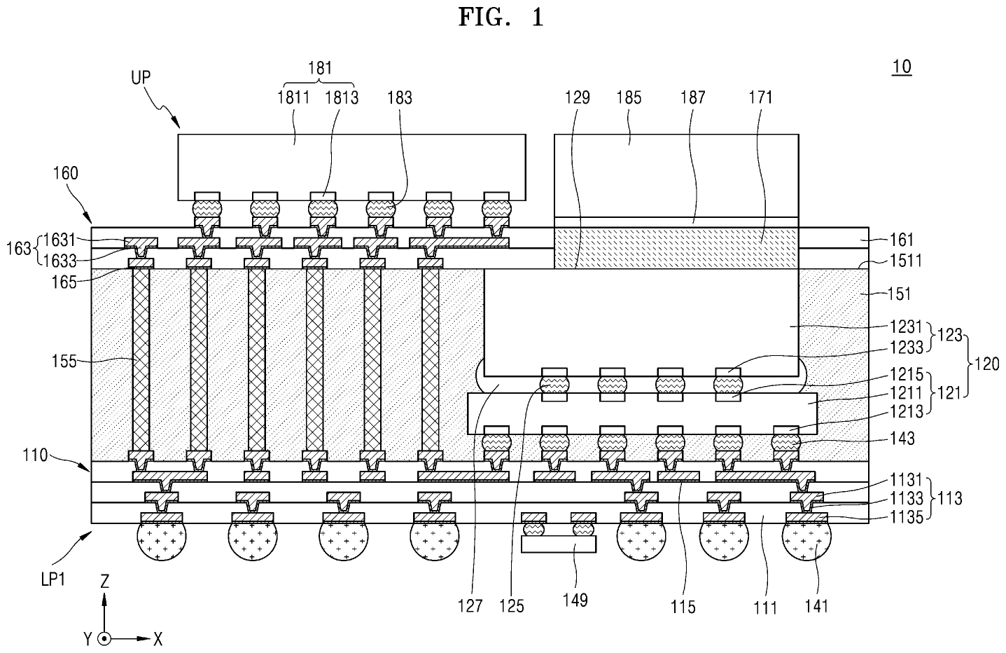

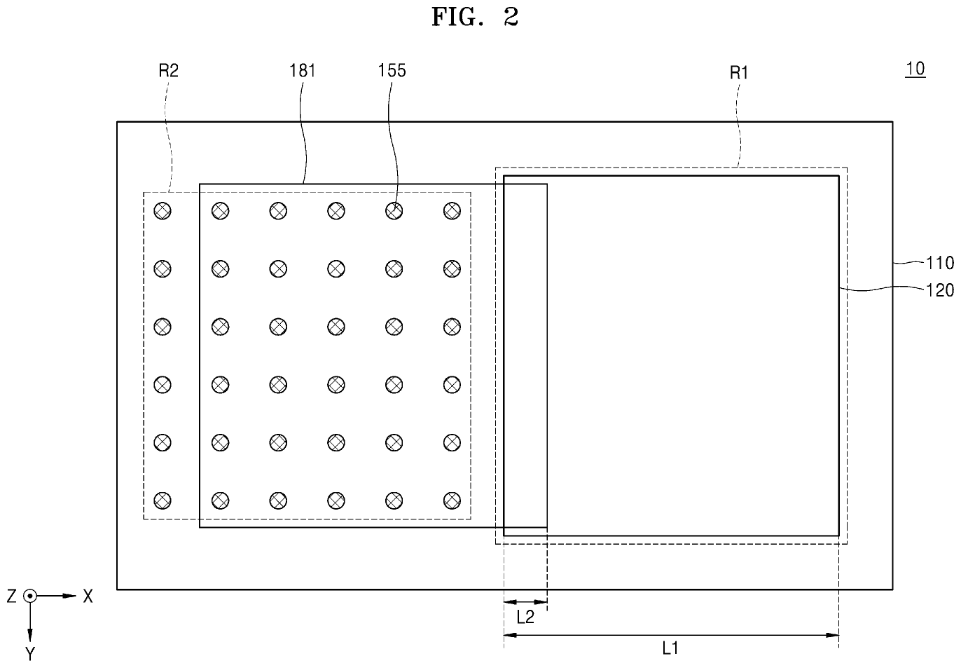

FIG. 1 is a cross-sectional view illustrating a semiconductor package 10 according to embodiments of the inventive concept. FIG. 2 is a layout diagram of main components of the semiconductor package 10 of FIG. 1.

Referring to FIGS. 1 and 2, the semiconductor package 10 may include a lower package LP1 and an upper package UP. The semiconductor package 10 may be a package-on-package type package in which an upper package UP is stacked or attached to a lower package LP1.

The lower package LP1 may include a first redistribution structure 110, a first lower semiconductor device 120, a molding layer 151, vertical connection conductors 155, a second redistribution structure 160, and a heat dissipation pad structure 171. The lower package LP1 may be a package having a fan-out structure. A footprint of the first redistribution structure 110 may be larger than that of the first lower semiconductor device 120. A footprint of the first redistribution structure 110 may be the same as that of the semiconductor package 10. As used herein, a semiconductor device may refer, for example, to a device such as a semiconductor chip (e.g., memory chip and/or logic chip formed on a die). The present disclosure is not limited thereto. In some embodiments, a semiconductor device may refer to a stack of semiconductor chips, a semiconductor package including one or more semiconductor chips stacked on a package substrate, or a package-on-package device including a plurality of packages.

The first redistribution structure 110 may be a package substrate on which mounting components, such as the first lower semiconductor device 120, may be attached. The first redistribution structure 110 may have a flat plate shape or a panel shape. The first redistribution structure 110 may include upper and lower surfaces opposite to each other, and the upper and lower surfaces of the first redistribution structure 110 may each be substantially planar. Hereinafter, the horizontal direction (e.g., the X direction and/or the Y direction) may be defined as a direction parallel to the upper or lower surface of the first redistribution structure 110, the vertical direction (e.g., the Z direction) may be defined as a direction perpendicular to the upper or lower surface of the first redistribution structure 110, and the horizontal width may be defined as a length in the horizontal direction (e.g., the X direction and/or the Y direction).

The first redistribution structure 110 may include a plurality of first redistribution insulating layers 111 and a first conductive redistribution pattern 113.

The plurality of first redistribution insulating layers 111 may be mutually stacked in the vertical direction (e.g., the Z direction). The plurality of first redistribution insulating layers 111 may be formed of an insulating polymer, epoxy, or a combination thereof. For example, each of the plurality of first redistribution insulating layers 111 may be formed of photo imageable dielectric (PID) or photosensitive polyimide (PSPI).

The first conductive redistribution pattern 113 may include first conductive layers 1131, first conductive via patterns 1133 (i.e., first conductive vias), and external connection pads 1135. Each of the first conductive layers 1131 may extend in the horizontal direction (e.g., the X direction and/or the Y direction) and may be disposed at different vertical levels to form a multilayer structure. The first conductive layers 1131 may be disposed on any one of upper and lower surfaces of each of the plurality of first redistribution insulating layers 111. For example, the first conductive layers 1131 may include line patterns extending in a line shape along any one of the upper and lower surfaces of any one of the plurality of first redistribution insulating layers 111. The first conductive layer 1131 provided on the uppermost insulating layer among the plurality of first redistribution insulating layers 111 may include pads to which first chip connection bumps 143 are attached and pads to which the vertical connection conductors 155 are attached. The first conductive via patterns 1133 may extend in the vertical direction (e.g., the Z direction) through at least one of the plurality of first redistribution insulating layers 111. The first conductive via patterns 1133 may electrically connect the first conductive layers 1131 disposed at different vertical levels to one another or may electrically connect the first conductive layer 1131 and the external connection pad 1135. The external connection pads 1135 may be disposed on the lower surface of the first redistribution structure 110 and each external connection pad may contact a corresponding external connection terminal 141. The external connection pads 1135 may be electrically connected to the first lower semiconductor device 120 and/or the vertical connection conductors 155 through the first conductive redistribution pattern 113. In example embodiments, when viewing a cross-section, the external connection pads 1135 may have a rectangular shape. The term “contact,” as used herein, refers to a direct connection (i.e., touching) unless the context indicates otherwise.

For example, the first conductive redistribution pattern 113 may include or may be formed of, for example, a metal such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof.

At least some of the plurality of first conductive layers 1131 may be integrally formed with some of the plurality of first conductive via patterns 1133. For example, some of the plurality of first conductive layers 1131 may be integrally formed with corresponding first conductive via patterns 1133 contacting lower sides thereof. For example, the first conductive layer 1131 and the first conductive via pattern 1133 connected to each other may be formed together through an electroplating process.

In example embodiments, each of the plurality of first conductive via patterns 1133 may have a tapered shape in which a horizontal width thereof narrows and extends in a direction from an upper side to a lower side thereof. The horizontal width of each of the plurality of first conductive via patterns 1133 may gradually decrease towards the upper surface of the external connection pad 1135.

A seed metal layer 115 may be disposed on the surface of the first conductive layer 1131 and the surface of the first conductive via pattern 1133. For example, the seed metal layer 115 may be disposed between the bottom surface of the first conductive layer 1131 and the first redistribution insulating layer 111, and may be disposed between each of the sidewall and the bottom surface of the first conductive via pattern 1133 and the first redistribution insulating layer 111. In addition, the seed metal layer 115 may be disposed between the first conductive via pattern 1133 and the external connection pad 1135. In addition, the seed metal layer 115 may be disposed between the external connection pad 1135 and the external connection terminal 141 along a lower surface of the external connection pad 1135. For example, the seed metal layer 115 may include at least one of copper (Cu), titanium (Ti), titanium tungsten (TiW), titanium nitride (TiN), tantalum (Ta), tantalum nitride (TaN), chromium (Cr), and aluminum (Al). For example, the seed metal layer 115 may be formed through a physical vapor deposition process, such as sputtering.

In example embodiments, the external connection pad 1135 may have a rectangular shape when viewing a cross-section. In example embodiments, a lower surface of the external connection pad 1135 may be substantially coplanar with a lower surface of the first redistribution insulating layer 111. For example, the external connection pad 1135 may be formed through an electroplating process. In example embodiments, the external connection pad 1135 may include a plurality of metal layers stacked in the vertical direction (e.g., the Z direction).

External connection terminals 141 may be respectively attached to the external connection pads 1135 of the first redistribution structure 110. The external connection terminals 141 may be configured to electrically and physically connect the first redistribution structure 110 to an external device. The external connection terminals 141 may be formed from, for example, solder balls or solder bumps.

One or more passive components 149 may be attached to the lower side of the first redistribution structure 110. The passive components 149 may be attached to the lower side of the first redistribution structure 110 through bumps made of solder.

The first redistribution structure 110 may include a first region R1 and a second region R2 spaced apart from each other. The first region R1 and the second region R2 may be regions provided in the upper surface of the first redistribution structure 110, and may be spaced apart from each other in the horizontal direction (e.g., the X direction and/or the Y direction).

The first lower semiconductor device 120 may be mounted on the first region R1 of the first redistribution structure 110. The first region R1 of the first redistribution structure 110 is a region vertically overlapped with the first lower semiconductor device 120, and a footprint of the first redistribution structure 110 may be substantially the same as that of the first lower semiconductor device 120.

The first lower semiconductor device 120 may be electrically and physically connected to the first conductive redistribution pattern 113 of the first redistribution structure 110 through the first chip connection bumps 143. Each of the first chip connection bumps 143 may be disposed between the first lower semiconductor device 120 and the first conductive layer 1131 provided on the uppermost insulating layer of the first redistribution insulating layer 111. The first chip connection bumps 143 may include or may be solder bumps.

In example embodiments, the first lower semiconductor device 120 may have a three-dimensional (3D) stacked structure including a plurality of semiconductor chips mutually stacked in the vertical direction (e.g., the Z direction). For example, the first lower semiconductor device 120 may include a lower semiconductor chip 121 and an upper semiconductor chip 123 on the lower semiconductor chip 121. The lower semiconductor chip 121 may include a lower semiconductor substrate 1211, lower connection pads 1213 provided in the lower side of the lower semiconductor substrate 1211 and respectively contacting the first chip connection bumps 143, and upper connection pads 1215 provided in the upper side of the lower semiconductor substrate 1211. The lower semiconductor chip 121 may further include through electrodes that penetrate the lower semiconductor substrate 1211 and electrically connect the lower connection pads 1213 and the upper connection pads 1215 to each other. The upper semiconductor chip 123 may include an upper semiconductor substrate 1231 and lower connection pads 1233 provided below the upper semiconductor substrate 1231. The upper connection pads 1215 of the lower semiconductor chip 121 may be electrically and physically connected to the lower connection pads 1233 of the upper semiconductor chip 123 through inter-chip connection bumps 125. A gap-fill insulating layer 127 surrounding sidewalls of the inter-chip connection bumps 125 may be disposed between the lower semiconductor chip 121 and the upper semiconductor chip 123. The gap-fill insulating layer 127 may be formed from, for example, a non-conductive film (NCF).

The lower semiconductor substrate 1211 and the upper semiconductor substrate 1231 may be formed from a semiconductor wafer. The lower semiconductor substrate 1211 and the upper semiconductor substrate 1231 may include or may be formed of, for example, silicon (Si). Alternatively, the lower semiconductor substrate 1211 and the upper semiconductor substrate 1231 may include or may be formed of a semiconductor element, such as germanium (Ge), or a compound semiconductor, such as silicon carbide (SiC), gallium arsenide (GaAs), indium arsenide (InAs), and indium phosphide (InP). The lower semiconductor substrate 1211 and the upper semiconductor substrate 1231 may include a conductive region, for example, a well doped with impurities or a structure doped with impurities. The lower semiconductor chip 121 may include or may be formed of a semiconductor element layer provided on an active surface (e.g., a lower surface of the lower semiconductor substrate 1211) of the lower semiconductor substrate 1211, and the upper semiconductor chip 123 may include or may be formed of a semiconductor element layer provided on an active surface (e.g., a lower surface of the upper semiconductor substrate 1231) of the upper semiconductor substrate 1231. The semiconductor element layer of the lower semiconductor chip 121 and the semiconductor element layer of the upper semiconductor chip 123 may each include individual elements. The individual elements may include, for example, transistors. The individual elements may include microelectronic devices, such as a metal-oxide-semiconductor field effect transistor (MOSFET), a system large scale integration (LSI), an image sensor, such as a CMOS imaging sensor (CIS), a micro-electro-mechanical system (MEMS), an active element, a passive element, and the like.

In example embodiments, the first lower semiconductor device 120 may include three or more semiconductor chips stacked in the vertical direction (e.g., the Z direction) or may include a single semiconductor chip.

The molding layer 151 may be disposed on the first redistribution structure 110. The molding layer 151 may cover at least a portion of the first lower semiconductor device 120 and an upper surface of the first redistribution structure 110. The molding layer 151 may extend along sidewalls of the first lower semiconductor device 120 and surround the sidewalls of the first lower semiconductor device 120. The molding layer 151 may not cover an upper surface 129 of the first lower semiconductor device 120. The upper surface 129 of the first lower semiconductor device 120 may be the upper surface of the upper semiconductor chip 123. In example embodiments, an upper surface 1511 of the molding layer 151 may be coplanar with the upper surface 129 of the first lower semiconductor device 120. Furthermore, the molding layer 151 may fill a gap between the first lower semiconductor device 120 and the first redistribution structure 110 and may surround sidewalls of the first chip connection bumps 143.

For example, the molding layer 151 may include or may be formed of an epoxy-based molding resin or a polyimide-based molding resin. In example embodiments, the molding layer 151 may include or may be formed of an epoxy molding compound.

The vertical connection conductors 155 may be disposed on the second region R2 of the first redistribution structure 110. The vertical connection conductors 155 may be configured to electrically connect between the first conductive redistribution pattern 113 of the first redistribution structure 110 and a second conductive redistribution pattern 163 of the second redistribution structure 160. The vertical connection conductors 155 may penetrate through the molding layer 151 in the vertical direction (e.g., the Z direction). The lower portion of each of the vertical connection conductors 155 may directly contact the first conductive layer 1131 provided on the uppermost insulating layer of the first redistribution insulating layer 111, and the upper portion of each of the vertical connection conductors 155 may directly contact the second conductive redistribution pattern 163. In example embodiments, upper surfaces of the vertical connection conductors 155 may be coplanar with the upper surface 1511 of the molding layer 151. The vertical connection conductors 155 may include or may be formed of, for example, copper (Cu).

The second redistribution structure 160 may be disposed on the molding layer 151 and the first lower semiconductor device 120. The second redistribution structure 160 may at least partially cover the upper surface 1511 of the molding layer 151 and may partially cover the upper surface 129 of the first lower semiconductor device 120. In embodiments, the footprint of the second redistribution structure 160 may be the same as that of the first redistribution structure 110. In embodiments, one sidewall of the second redistribution structure 160 may be aligned in the vertical direction (e.g., Z direction) with corresponding sidewalls of the molding layer 151 and corresponding sidewalls of the first redistribution structure 110.

The second redistribution structure 160 may include a plurality of second redistribution insulating layers 161 and a second conductive redistribution pattern 163.

The plurality of second redistribution insulating layers 161 may be mutually stacked in the vertical direction (e.g., the Z direction). The plurality of second redistribution insulating layers 161 may be formed of an insulating polymer, epoxy, or a combination thereof. For example, each of the plurality of second redistribution insulating layers 161 may be formed from PID or PSPI.

The second conductive redistribution pattern 163 may include second conductive layers 1631 and second conductive via patterns 1633 (i.e., second conductive vias). The second conductive layers 1631 may be disposed on any one of the upper and lower surfaces of any one of the plurality of second redistribution insulating layers 161. The second conductive layers 1631 may be disposed at different vertical levels to form a multilayer structure. For example, the second conductive layers 1631 may include a line pattern extending in a line shape along the upper or lower surface of any one of the plurality of second redistribution insulating layers 161. The second conductive layer 1631 provided on the uppermost insulating layer among the plurality of second redistribution insulating layers 161 may include pads to which connection terminals 183 are attached. Among the second conductive layers 1631, the lowermost second conductive layer 1631 may include pads attached to the vertical connection conductors 155. The second conductive via patterns 1633 may extend in the vertical direction (e.g., the Z direction) through at least one insulating layer among the plurality of second redistribution insulating layers 161. The second conductive via patterns 1633 may electrically connect between the second conductive layers 1631 disposed at different vertical levels, or may electrically connect between the second conductive layer 1631 and the vertical connection conductor 155. For example, the second conductive redistribution pattern 163 may include or may be formed of, for example, a metal such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and an alloy thereof.

At least some of the plurality of second conductive layers 1631 may be integrally formed with some of the plurality of second conductive via patterns 1633. For example, some of the plurality of second conductive layers 1631 may be integrally formed with corresponding second conductive via patterns 1633 contacting lower sides thereof. For example, the second conductive layer 1631 and the second conductive via pattern 1633 connected to each other may be formed together through an electroplating process. A seed metal layer 165 may be disposed on the surface of the second conductive layer 1631 and the surface of the second conductive via pattern 1633. For example, the seed metal layer 165 may be disposed between the bottom surface of the second conductive layer 1631 and the second redistribution insulating layer 161, and may be disposed between each of the sidewall and the bottom surface of the second conductive via pattern 1633 and the second redistribution insulating layer 161. For example, the seed metal layer 165 may include or may be formed of at least one of copper (Cu), titanium (Ti), titanium tungsten (TiW), titanium nitride (TiN), tantalum (Ta), tantalum nitride (TaN), chromium (Cr), and aluminum (Al).

In example embodiments, each of the plurality of second conductive via patterns 1633 may have a tapered shape in which a horizontal width thereof narrows and extends in a direction from an upper side to a lower side thereof. In other words, the horizontal width of each of the plurality of second conductive via patterns 1633 may gradually decrease towards the upper surface 1511 of the molding layer 151 or the upper surface of the vertical connection conductor 155.

The heat dissipation pad structure 171 may contact the upper surface 129 of the first lower semiconductor device 120. The heat dissipation pad structure 171 is thermally coupled to the first lower semiconductor device 120, and may not be electrically connected to the first lower semiconductor device 120, the second conductive redistribution pattern 163, and the vertical connection conductors 155. The term “thermally coupled to” may refer to a connection through which heat is transferred. For example, the heat generated by the first lower semiconductor device 120 may be dissipated by the heat dissipation pad structure 171 that is thermally coupled to the first lower semiconductor device 120. The heat dissipation pad structure 171 may vertically penetrate the second redistribution insulating layer 161 of the second redistribution structure 160 and directly contact the upper surface 129 of the first lower semiconductor device 120. The heat dissipation pad structure 171 may extend along a portion of the upper surface 129 of the first lower semiconductor device 120 and cover a portion of the upper surface 129 of the first lower semiconductor device 120. For example, a portion of the upper surface 129 of the first lower semiconductor device 120 may directly contact the heat dissipation pad structure 171, and another portion of the upper surface 129 of the first lower semiconductor device 120 may directly contact the second redistribution insulating layer 161.

In embodiments, the heat dissipation pad structure 171 may be disposed in a through hole of the second redistribution insulating layer 161 of the second redistribution structure 160, and may at least partially fill the through hole of the second redistribution insulating layer 161 of the second redistribution structure 160. For example, the heat dissipation pad structure 171 may entirely fill the through hole of the second redistribution insulating layer 161 and may extend from the lower surface to the upper surface of the second redistribution insulating layer 161.

The heat dissipation pad structure 171 may include or may be formed of a material having excellent thermal conductivity, for example, metal. In example embodiments, the heat dissipation pad structure 171 may include or may be formed of copper (Cu) or aluminum (Al). The heat dissipation pad structure 171 may transfer heat generated from the first lower semiconductor device 120 to the outside of the semiconductor package 10 and/or to a heat dissipation plate 185. In example embodiments, the heat dissipation pad structure 171 may be formed together with the second conductive redistribution pattern 163 of the second redistribution structure 160 through the same metal interconnect process. In this case, the material and/or material composition of the heat dissipation pad structure 171 may be substantially the same as the material and/or material composition of the second conductive redistribution pattern 163. In example embodiments, the heat dissipation pad structure 171 may be formed through a process different from the process of forming the second conductive redistribution pattern 163 of the second redistribution structure 160. In example embodiments, a material and/or material composition of the heat dissipation pad structure 171 may be different from a material and/or material composition of the second conductive redistribution pattern 163.

The upper package UP may be disposed on the second redistribution structure 160. The upper package UP may include at least one upper semiconductor device 181 disposed on the second redistribution structure 160. The upper semiconductor device 181 may include a semiconductor chip and/or a package including the semiconductor chip. For example, the upper semiconductor device 181 may include a semiconductor substrate 1811 and chip pads 1813. The chip pads 1813 of the upper semiconductor device 181 may be electrically and physically connected to the second conductive redistribution pattern 163 of the second redistribution structure 160 through connection terminals 183.

In embodiments, the first lower semiconductor device 120 and the upper semiconductor device 181 may include different types of semiconductor chips, and may be electrically connected to each other through the first conductive redistribution pattern 113 of the first redistribution structure 110, the vertical connection conductors 155, and the second conductive redistribution pattern 163 of the second redistribution structure 160. The first lower semiconductor device 120 and the upper semiconductor device 181 may include a memory chip, a logic chip, a system on chip (SoC), a power management integrated circuit (PMIC) chip, and a radio frequency integrated circuit (RFIC) chip. The memory chip may include a DRAM chip, an SRAM chip, an MRAM chip, a Nand flash memory chip, and/or a high bandwidth memory (HBM) chip. The logic chip may include an application processor (AP), a microprocessor, a central processing unit (CPU), a controller, and/or an application specific integrated circuit (ASIC). For example, the SoC may include at least two circuits among a logic circuit, a memory circuit, a digital integrated circuit (IC), an RFIC, and an input/output circuit.

The heat dissipation plate 185 may vertically overlap a portion of the first lower semiconductor device 120 and may be attached to the heat dissipation pad structure 171. The heat dissipation plate 185 may be spaced apart from the upper semiconductor device 181 in a lateral direction (e.g., in the X direction) and may overlap the upper semiconductor device 181 in a lateral direction (e.g., in the X direction). The heat dissipation plate 185 may be thermally coupled to the first lower semiconductor device 120 through the heat dissipation pad structure 171. The heat dissipation plate 185 may include a heat sink, heat pipe, and/or heat slug. Heat generated in the first lower semiconductor device 120 may be dissipated to the outside through the heat dissipation pad structure 171 and the heat dissipation plate 185. The heat dissipation plate 185 may include or may be formed of a thermally conductive material having high thermal conductivity. The thermal conductivity of a material constituting the heat dissipation plate 185 may be greater than the thermal conductivity of silicon. In other words, the thermal resistance of the material constituting the heat dissipation plate 185 may be less than that of silicon. For example, the heat dissipation plate 185 may include or may be formed of a metal, such as copper (Cu) and aluminum (Al), or a carbon-containing material, such as graphene, graphite, and carbon nanotubes.

The heat dissipation plate 185 may be attached to the first lower semiconductor device 120 through the thermally conductive adhesive layer 187. The thermally conductive adhesive layer 187 may include or may be formed of a material that is thermally conductive and electrically insulating. The thermally conductive adhesive layer 187 may include or may be formed of a thermal interface material, a polymer including metal powder, thermal grease, or a combination thereof.

In example embodiments, the amount of heat generated by the first lower semiconductor device 120 may be greater than that of the amount of heat generated by the upper semiconductor device 181. In example embodiments, the first lower semiconductor device 120 may include a logic chip and/or an SoC. In example embodiments, the upper semiconductor device 181 may include a memory chip. According to embodiments of the inventive concept, since the first lower semiconductor device 120 having a relatively high heat generation value is thermally coupled to the heat dissipation plate 185 through the heat dissipation pad structure 171, heat dissipation characteristics of the first lower semiconductor device 120 may be improved, and performance degradation of electronic components around the first lower semiconductor device 120 due to heat generated by the first lower semiconductor device 120 may be prevented.

The upper semiconductor device 181 may vertically overlap a portion of the first lower semiconductor device 120. In embodiments, when viewed from the top, a portion of the upper semiconductor device 181 may vertically overlap the first region R1 of the first redistribution structure 110 on which the first lower semiconductor device 120 is mounted, and another portion of the upper semiconductor device 181 may vertically overlap the second region R2 of the first redistribution structure 110 in which the vertical connection conductors 155 are disposed.

In embodiments, when viewed from the top, a first portion of the first lower semiconductor device 120 vertically overlaps the upper semiconductor device 181, and a second portion of the first lower semiconductor device 120 may not vertically overlap the upper semiconductor device 181. The second portion of the first lower semiconductor device 120 may be another portion of the first lower semiconductor device 120 other than the first portion of the first lower semiconductor device 120. In embodiments, the ratio between a first length L2 in the first lateral direction (e.g., X direction) of the first portion of the first lower semiconductor device 120 vertically overlapping the upper semiconductor device 181 to the total length L1 in the first lateral direction (e.g., X direction) of the first lower semiconductor device 120 may be between 10% and 45%, between 20% and 40%, or between 25% and 35%. If the ratio between the first length L2 to the total length L1 is less than 10%, it may be difficult to sufficiently reduce the footprint of the semiconductor package 10. If the ratio between the first length L2 to the total length L1 is greater than 45%, it may be difficult to sufficiently dissipate heat from the first lower semiconductor device 120.

In the semiconductor package 10, a signal (e.g., a data signal, a control signal, a power signal, and/or a ground signal) provided from an external device may be provided to the first lower semiconductor device 120 through a signal transmission path including the external connection terminal 141 and the first conductive redistribution pattern 113. A signal (e.g., a data signal, a control signal, a power signal, and/or a ground signal) provided from an external device may be provided to the upper semiconductor device 181 through a signal transmission path including the external connection terminal 141, the first conductive redistribution pattern 113, the vertical connection conductor 155, and the second conductive redistribution pattern 163. Between the first lower semiconductor device 120 and the upper semiconductor device 181, electrical signals may be transmitted through the first conductive redistribution pattern 113, the vertical connection conductor 155, and the second conductive redistribution pattern 163.

In a typical semiconductor package, when semiconductor chips are arranged side-by-side along an upper surface of a package substrate, the dimensions of the semiconductor package (i.e., dimensions in the horizontal direction (X direction and/or Y direction)) may be increased. In addition, when a semiconductor chip of an upper package is disposed overlapping a semiconductor chip of a lower package, it is difficult to dissipate heat generated from the semiconductor chip of the lower package to the outside.

According to embodiments of the inventive concept, since a part of the first lower semiconductor device 120 vertically overlaps the upper semiconductor device 181 and another part of the first lower semiconductor device 120 is thermally coupled to the heat dissipation plate 185, it is possible to provide the semiconductor package 10 with improved heat dissipation characteristics while miniaturizing the footprint.

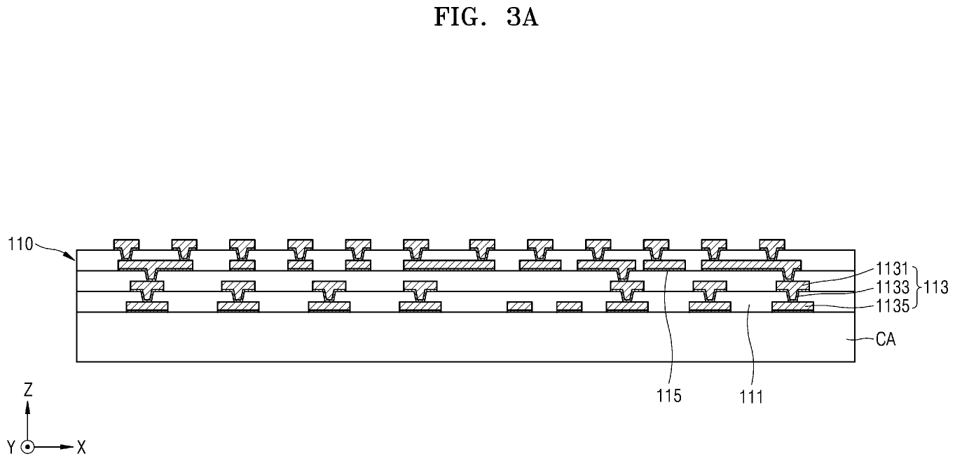

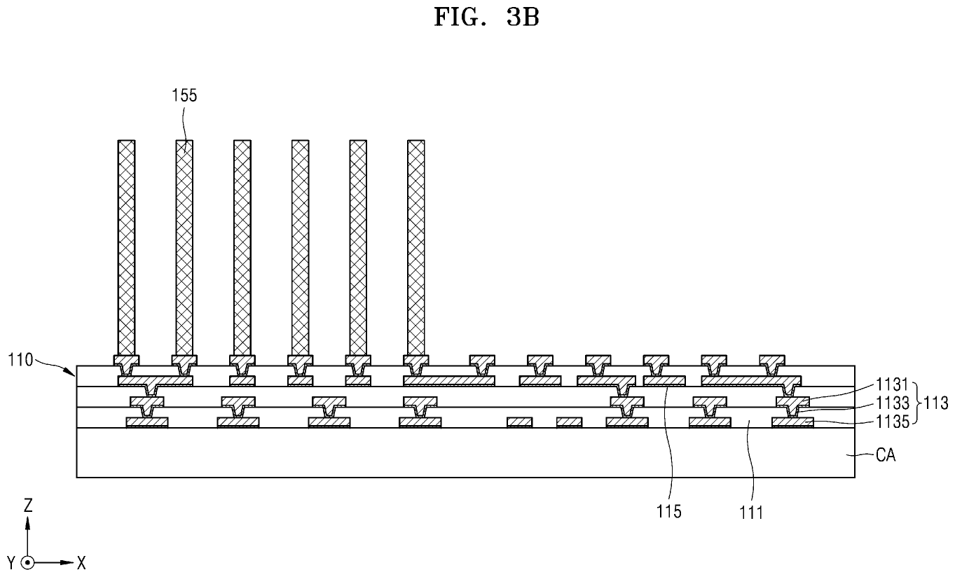

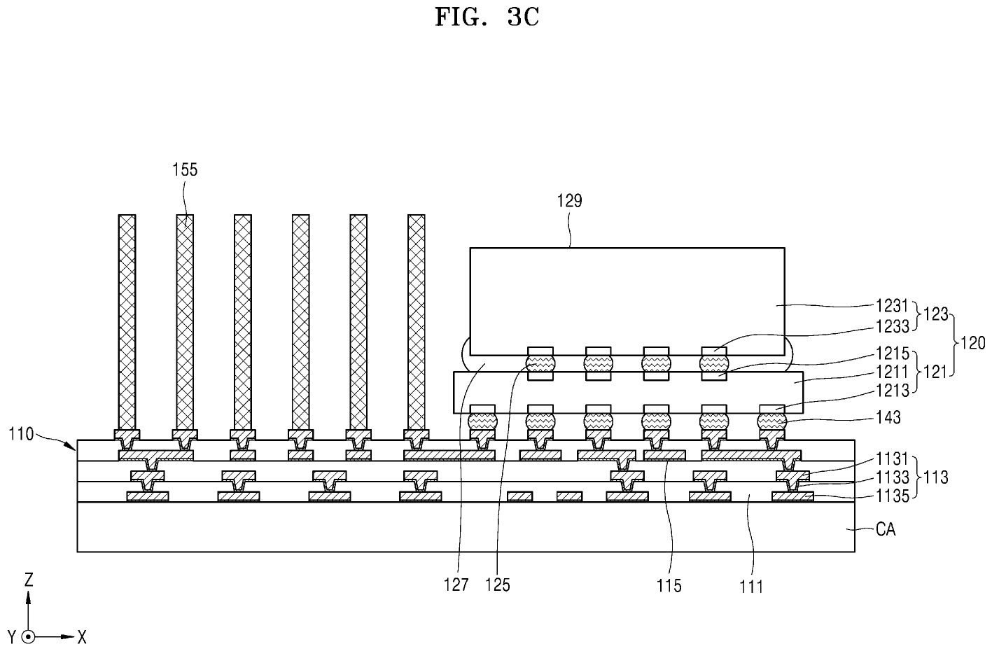

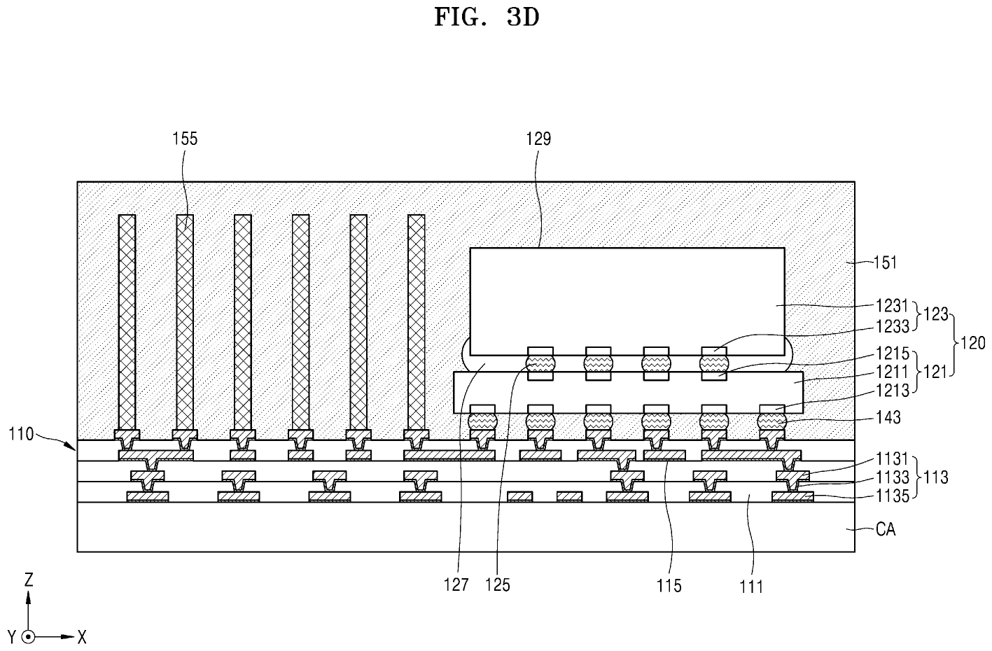

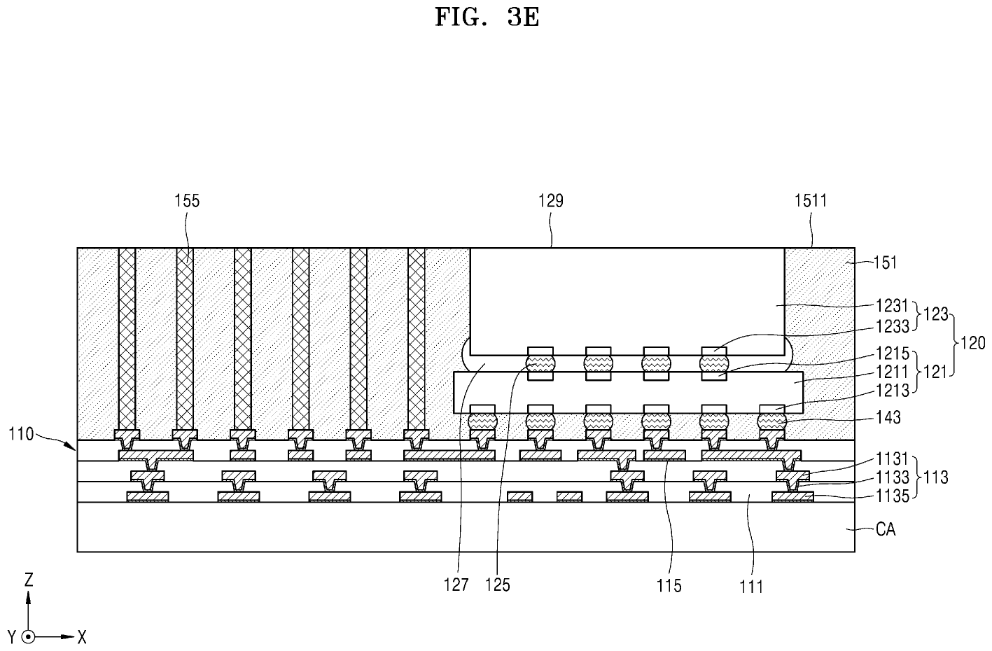

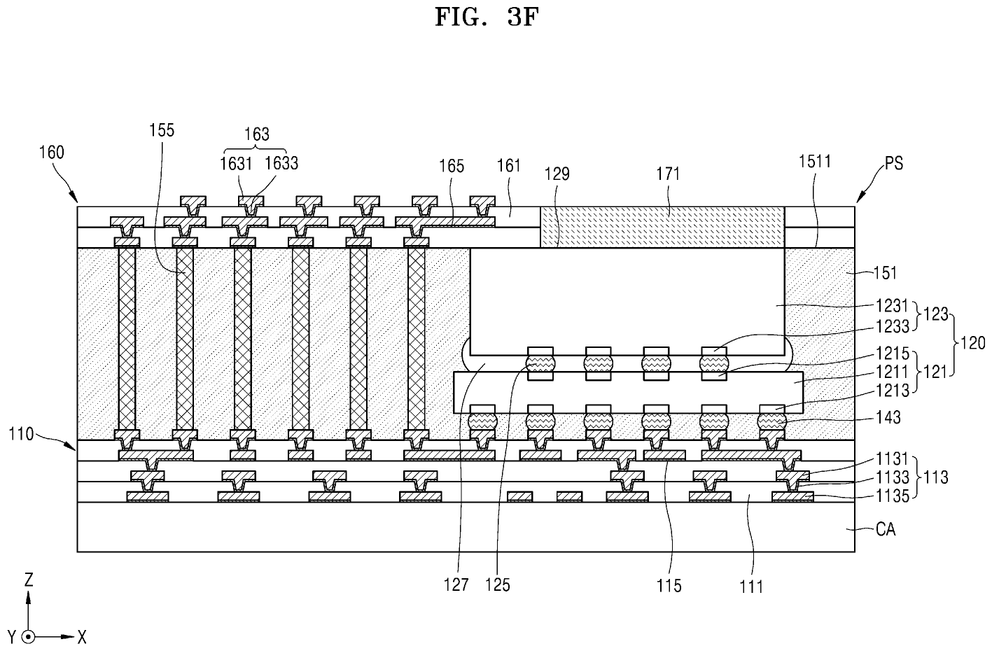

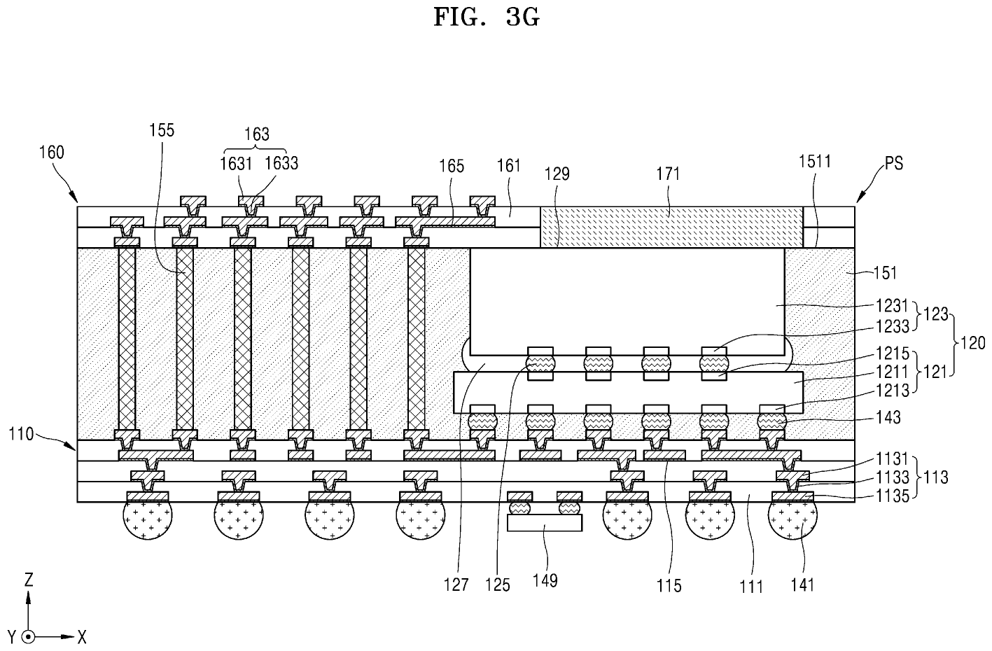

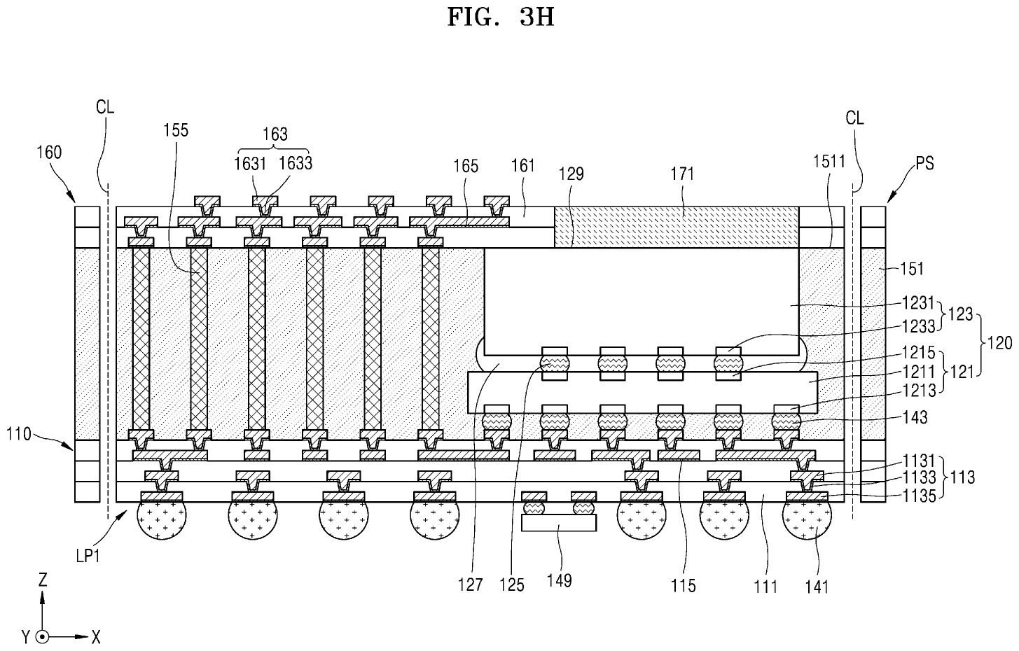

FIGS. 3A to 3H are cross-sectional views illustrating a method of manufacturing a semiconductor package 10, according to embodiments of the inventive concept. Hereinafter, a method of manufacturing the semiconductor package 10 described with reference to FIGS. 1 and 2 is described with reference to FIGS. 3A to 3H.

Referring to FIG. 3A, a first redistribution structure 110 is formed on a carrier substrate CA. The first redistribution structure 110 may include a plurality of first redistribution insulating layers 111 sequentially stacked on the carrier substrate CA, and a first conductive redistribution pattern 113 insulated by the plurality of first redistribution insulating layers 111. The first conductive redistribution pattern 113 may include the external connection pad 1135 extending along the upper surface of the carrier substrate CA, the first conductive layers 1131 extending along upper surfaces of the plurality of first redistribution insulating layers 111, and the conductive via patterns extending in the plurality of first redistribution insulating layers 111.

To form the first redistribution structure 110, external connection pads 1135 may be first formed on the carrier substrate CA. The external connection pad 1135 may be formed through a plating process. For example, after forming the seed metal layer 115 on the carrier substrate CA, a plating process using the seed metal layer 115 may be performed to form the external connection pad 1135. After forming the external connection pad 1135, a first step of forming an insulating film covering the external connection pad 1135 and having a via hole and a second step of forming a first conductive via pattern 1133 filling the via hole of the insulating layer and a first conductive layer 1131 extending along an upper surface of the insulating layer may be performed. The second step of forming the first conductive via pattern 1133 and the first conductive layer 1131 may include a plating process using the seed metal layer 115. Thereafter, the first redistribution structure 110 having a multi-layer interconnect structure may be formed by repeating the first step of forming the insulating film and the second step of forming the first conductive layer 1131 several times.

Referring to FIG. 3B, vertical connection conductors 155 are formed on the first redistribution structure 110. The vertical connection conductors 155 may be formed using a plating process.

Referring to FIG. 3C, the first lower semiconductor device 120 is mounted on the first redistribution structure 110. The first lower semiconductor device 120 may be mounted on the first redistribution structure 110 through the first chip connection bumps 143.

Referring to FIG. 3D, a molding layer 151 covering the first lower semiconductor device 120 and the vertical connection conductors 155 is formed on the first redistribution structure 110. To form the molding layer 151, a molding material may be supplied on the carrier substrate CA, and then the molding material may be cured.

Referring to FIGS. 3D and 3E, a portion of the molding layer 151 may be removed to expose the first lower semiconductor device 120 and the vertical connection conductors 155. To remove a portion of the molding layer 151, a chemical mechanical polishing (CMP) process, a grinding process, or the like may be performed. For example, a portion of the molding layer 151, a portion of each of the vertical connection conductors 155, and a portion of the first lower semiconductor device 120 may be removed through a polishing process. In example embodiments, as a result of the polishing process, the polished upper surface 1511 of the molding layer 151 may be coplanar with the upper surface 129 of the first lower semiconductor device 120 and the upper surface of each of the vertical connection conductors 155.

Referring to FIG. 3F, the second redistribution structure 160 is formed on the upper surface 1511 of the molding layer 151 and the upper surface 129 of the first lower semiconductor device 120. The second redistribution structure 160 may include a plurality of second redistribution insulating layers 161 sequentially stacked on the upper surface 1511 of the molding layer 151 and the upper surface 129 of the first lower semiconductor device 120 and a second conductive redistribution pattern 163 insulated by a plurality of second redistribution insulating layers 161. The second conductive redistribution pattern 163 may include the second conductive layers 1631 extending along upper surfaces of the plurality of second redistribution insulating layers 161, and the second conductive via patterns 1633 extending it the plurality of second redistribution insulating layers 161.

To form the second redistribution structure 160, a lowermost second conductive layer 1631 connected to the vertical connection conductors 155 may be formed. For example, after forming the seed metal layer 165 on the vertical connection conductors 155, a plating process using the seed metal layer 115 may be performed to form the lowermost second conductive layer 1631. Next, a first step of forming an insulating film covering the lowermost second conductive layer 1631 and having a via hole and a second step of forming a second conductive via pattern 1633 filling the via hole of the insulating layer and a second conductive layer 1631 extending along the upper surface of the insulating layer may be performed. The second step of forming the second conductive via pattern 1633 and the second conductive layer 1631 may include a plating process using the seed metal layer 165. Thereafter, the second redistribution structure 160 having a multi-layer interconnect structure may be formed by repeating the first step of forming the insulating film and the second step of forming the second conductive layer 1631 several times.

After forming the second redistribution structure 160, a through hole is formed in the second redistribution insulating layer 161, and a heat dissipation pad structure 171 is formed in the through hole of the second redistribution insulating layer 161. For example, to form the heat dissipation pad structure 171, a through hole partially exposing the upper surface 129 of the first lower semiconductor device 120 may be formed in the second redistribution insulating layer 161, and the through hole may be filled with a conductive material.

A first redistribution structure 110, a first lower semiconductor device 120, vertical connection conductors 155, a molding layer 151, a second redistribution structure 160, and a heat dissipation pad structure 171 may form a panel-shaped package structure PS.

Referring to FIGS. 3F and 3G, the carrier substrate CA is removed from the first redistribution structure 110. Then, external connection terminals 141 and passive components 149 are attached to the lower side of the first redistribution structure 110.

Referring to FIG. 3H, the package structure PS may be cut along the cutting line CL. Through a process of cutting the package structure PS, the package structure PS may be separated into a plurality of lower packages LP1.

Next, referring to FIG. 1, the upper package UP and the heat dissipation plate 185 are attached to the lower package LP1 separated as an individual unit. The upper semiconductor device 181 constituting the upper package UP may be mounted on the second redistribution structure 160 so as to vertically overlap a portion of the first lower semiconductor device 120, and the heat dissipation plate 185 may be attached on the heat dissipation pad structure 171 through the thermally conductive adhesive layer 187.

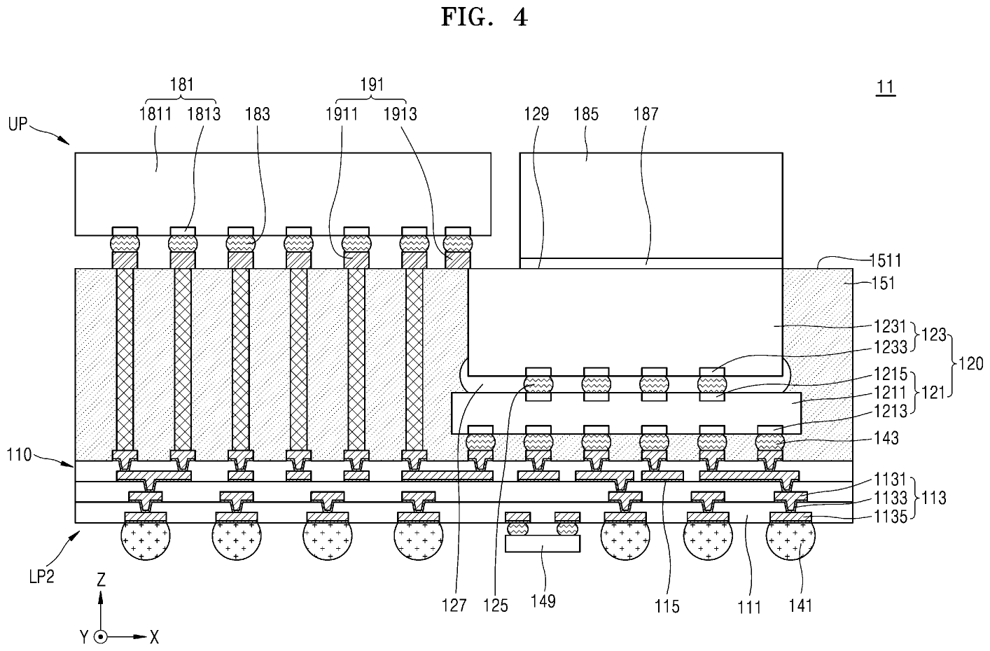

FIG. 4 is a cross-sectional view illustrating a semiconductor package 11 according to embodiments of the inventive concept. Hereinafter, the semiconductor package 11 shown in FIG. 4 is described focusing on the differences from the semiconductor package 10 described with reference to FIGS. 1 and 2.

Referring to FIG. 4, the lower package LP2 of the semiconductor package 11 may include the conductive layer 191 provided on the upper surface 1511 of the molding layer 151. The conductive layer 191 may include conductive pads 1911 connected to upper surfaces of the vertical connection conductors 155 and one or more dummy pads 1913 not connected to the vertical connection conductors 155. One or more dummy pads 1913 may be disposed on the upper surface 1511 of the molding layer 151 and/or the upper surface 129 of the first lower semiconductor device 120. A material of the conductive layer 191 may be substantially the same as or similar to that of the first conductive layer 1131. The upper semiconductor device 181 of the upper package UP may be disposed on the conductive pads 1911 and one or more dummy pads 1913 of the conductive layer 191 through connection terminals 183. The upper semiconductor device 181 may be electrically and physically connected to the vertical connection conductors 155 through the conductive pads 1911 of the conductive layer 191. Also, in the semiconductor package 11, the heat dissipation plate 185 may be attached to the upper surface 129 of the first lower semiconductor device 120 by a thermally conductive adhesive layer 187.

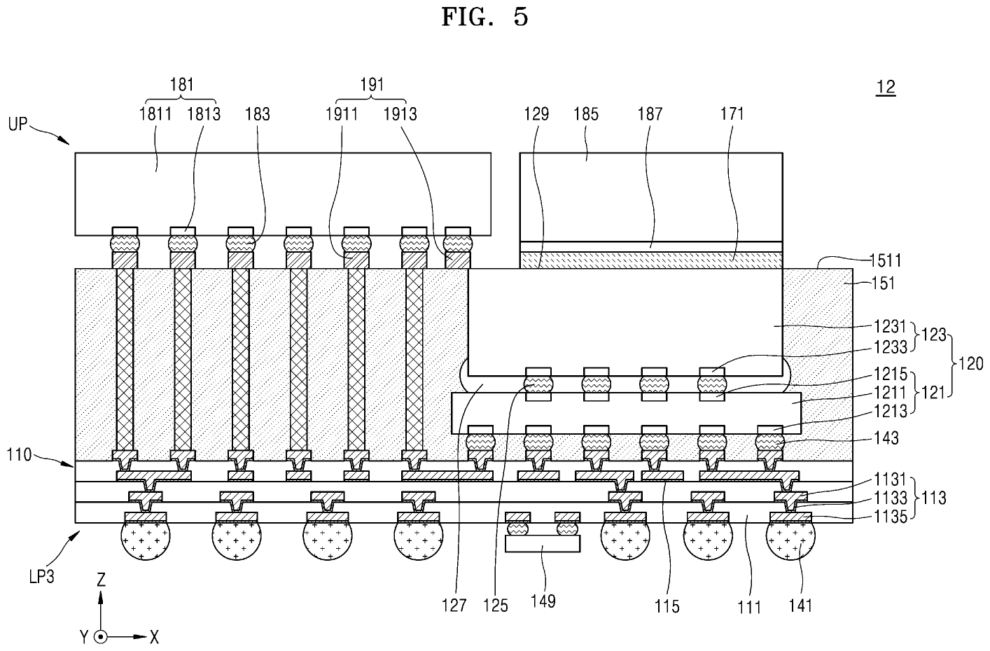

FIG. 5 is a cross-sectional view illustrating a semiconductor package 12 according to embodiments of the inventive concept. Hereinafter, the semiconductor package 12 shown in FIG. 5 is described focusing on the differences from the semiconductor package 11 described with reference to FIG. 4.

Referring to FIG. 5, in the lower package LP3 of the semiconductor package 12, a heat dissipation pad structure 171 may be disposed on the upper surface 129 of the first lower semiconductor device 120. A heat dissipation plate 185 may be attached to the heat dissipation pad structure 171. The heat dissipation pad structure 171 may have a plate shape covering the upper surface 129 of the first lower semiconductor device 120. The heat dissipation pad structure 171 may be formed through the same metal interconnect process as the conductive layer 191. A thickness of the heat dissipation pad structure 171 may be substantially the same as that of the conductive layer 191. A material of the heat dissipation pad structure 171 may be substantially the same as that of the conductive layer 191.

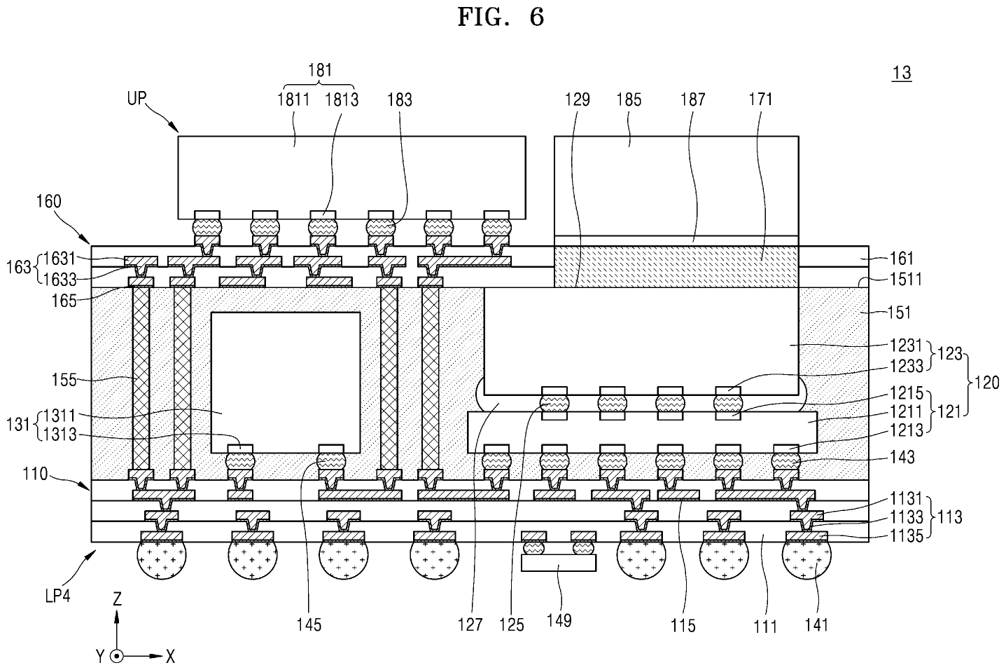

FIG. 6 is a cross-sectional view illustrating a semiconductor package 13 according to embodiments of the inventive concept. Hereinafter, the semiconductor package 13 shown in FIG. 6 will be described focusing on the differences from the semiconductor package 10 described with reference to FIGS. 1 and 2.

Referring to FIG. 6, in the semiconductor package 13, the lower package LP4 may further include the second lower semiconductor device 131 mounted on the second region R2 of FIG. 2 of the first redistribution structure 110. In example embodiments, the second lower semiconductor device 131 may include any one of a memory chip, a logic chip, an SoC, a PMIC chip, and an RFIC chip.

The second lower semiconductor device 131 may include a semiconductor substrate 1311 and chip pads 1313. The second lower semiconductor device 131 may be mounted on the first redistribution structure 110 in a flip chip method. In this case, the lower surface of the semiconductor substrate 1311 may be an active surface of the semiconductor substrate 1311, and the upper surface of the semiconductor substrate 1311 may be an inactive surface of the semiconductor substrate 1311. A semiconductor element layer of the second lower semiconductor device 131 may be disposed on a lower surface of the semiconductor substrate 1311, and chip pads 1313 may be provided in a lower surface of the second lower semiconductor device 131. Second chip connection bumps 145 configured to electrically connect the chip pads 1313 of the second lower semiconductor device 131 to the first conductive redistribution pattern 113 may be disposed between the chip pads 1313 of the second lower semiconductor device 131 and the first redistribution structure 110. The second lower semiconductor device 131 may be spaced apart from the first lower semiconductor device 120 in a lateral direction (e.g., the X direction) and may vertically overlap the upper semiconductor device 181. In some embodiments, an entire upper surface of the second lower semiconductor device 131 may vertically overlap the upper semiconductor device 181. The second lower semiconductor device 131 may be electrically connected to the first lower semiconductor device 120 through the first conductive redistribution pattern 113. The second lower semiconductor device 131 may be electrically connected to the upper semiconductor device 181 through the first conductive redistribution pattern 113, the vertical connection conductors 155, and the second conductive redistribution pattern 163. In an embodiment, the second lower semiconductor device 131 may be buried in the molding layer 151. For example, the molding layer 151 may cover an upper surface of the second lower semiconductor device 131 and side surfaces thereof. In some embodiments, the molding layer 151 may further cover a lower surface of the second lower semiconductor device 131.

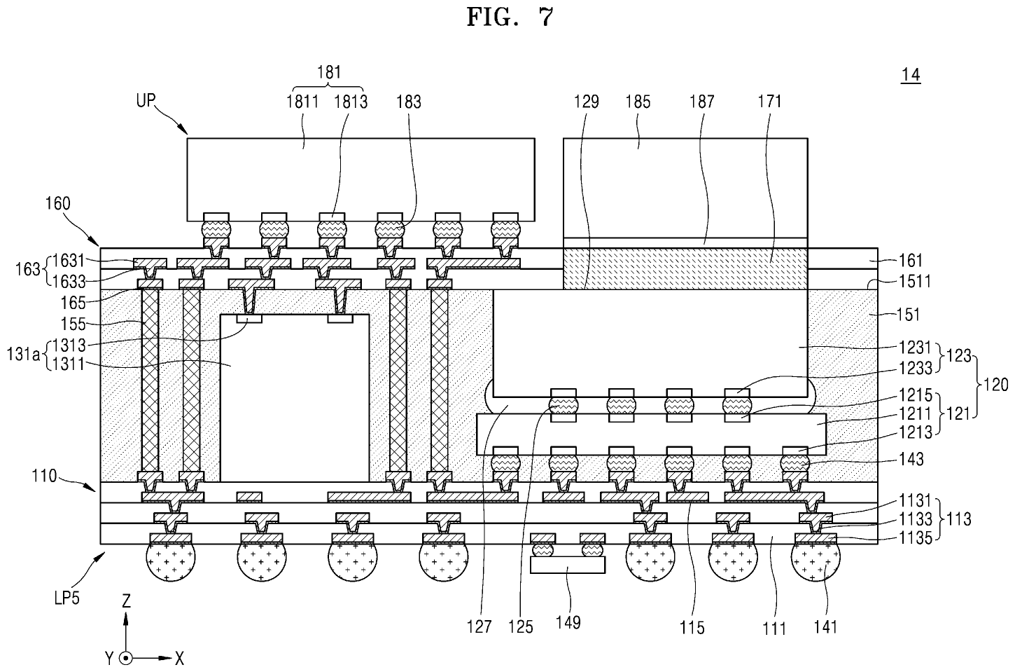

FIG. 7 is a cross-sectional view illustrating a semiconductor package 14 according to embodiments of the inventive concept. Hereinafter, the semiconductor package 14 shown in FIG. 7 will be described focusing on the differences from the semiconductor package 13 described with reference to FIG. 6.

Referring to FIG. 7, in the lower package LP5 of the semiconductor package 14, the second lower semiconductor device 131a may be mounted on the first redistribution structure 110 in a face-up manner. A lower surface of the semiconductor substrate 1311 may be an inactive surface of the semiconductor substrate 1311, and an upper surface of the semiconductor substrate 1311 may be an active surface of the semiconductor substrate 1311. A semiconductor element layer of the second lower semiconductor device 131a may be disposed on an upper surface of the semiconductor substrate 1311, and a chip pad 1313 may be provided in an upper surface of the second lower semiconductor device 131a. In the second redistribution structure 160, some of the plurality of second conductive via patterns 1633 may penetrate through the molding layer 151 and be connected to the chip pads 1313 of the second lower semiconductor device 131a. The second lower semiconductor device 131a may be electrically connected to the upper semiconductor device 181 through the second conductive redistribution pattern 163. In an embodiment, the second lower semiconductor device 131a may be buried in the molding layer 151. For example, an upper surface of the second lower semiconductor device 131a and side surfaces thereof may be covered with the molding layer 151, and a lower surface of the second lower semiconductor device 131a may contact the upper surface of the first redistribution structure 110.

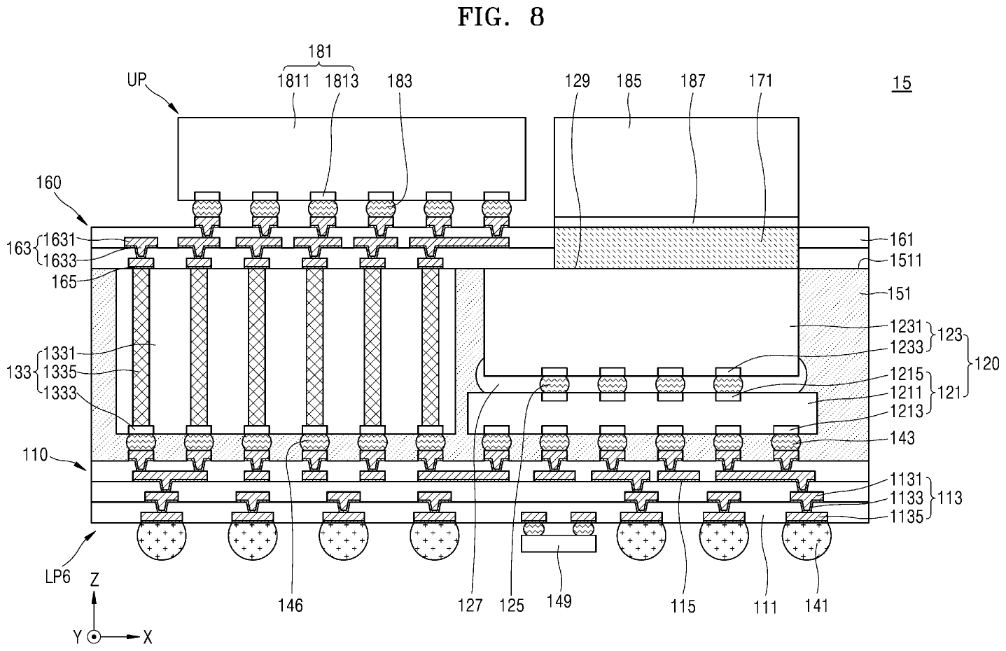

FIG. 8 is a cross-sectional view illustrating a semiconductor package 15 according to embodiments of the inventive concept. Hereinafter, the semiconductor package 15 shown in FIG. 8 is described focusing on the differences from the semiconductor package 10 described with reference to FIGS. 1 and 2.

Referring to FIG. 8, in the semiconductor package 15, the lower package LP6 may further include a dummy chip 133 mounted on the second region R2 of FIG. 2 of the first redistribution structure 110. The dummy chip 133 may be mounted on the first redistribution structure 110 through the dummy connection bumps 146. The dummy chip 133 may include a dummy semiconductor substrate 1331, dummy connection pads 1333 provided on the lower surface of the dummy semiconductor substrate 1331 and connected to the dummy connection bumps 146, and vertical connection conductors 1335 extending through the dummy semiconductor substrate 1331. The dummy chip 133 provides an electrical signal path extending in the vertical direction (e.g., Z direction) in the semiconductor package 15, but does not include individual elements, such as transistors. The first lower semiconductor device 120 and the upper semiconductor device 181 may be electrically connected to each other through a signal transmission path including the first conductive redistribution pattern 113, dummy connection bumps 146, the dummy connection pads 1333, the vertical connection conductors 1335, and the second conductive redistribution pattern 163.

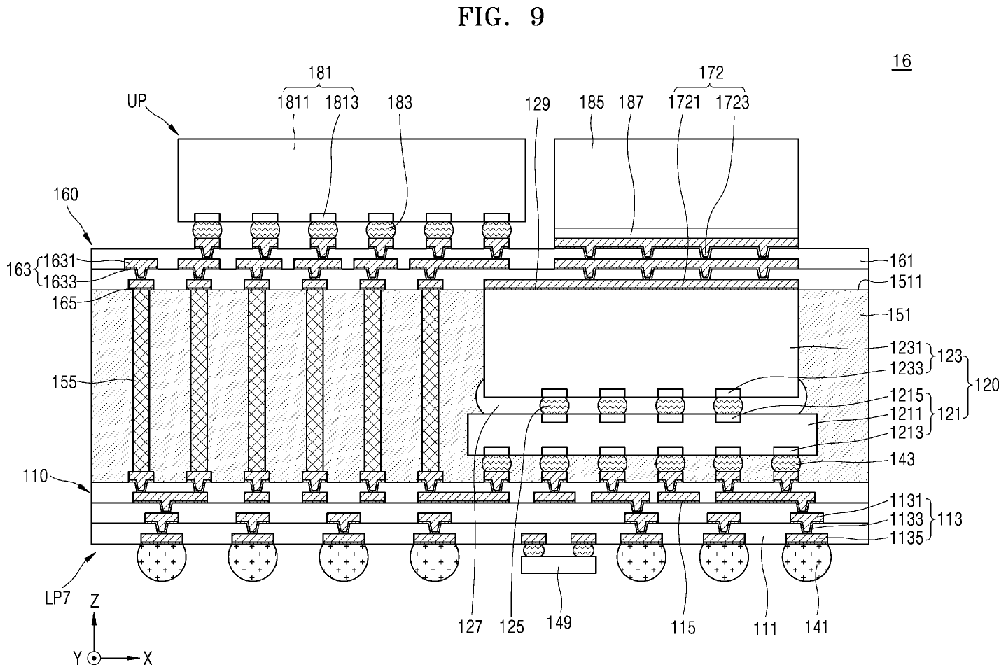

FIG. 9 is a cross-sectional view illustrating a semiconductor package 16 according to embodiments of the inventive concept. Hereinafter, the semiconductor package 16 shown in FIG. 9 is described focusing on the differences from the semiconductor package 10 described with reference to FIGS. 1 and 2.

Referring to FIG. 9, in the lower package LP7 of the semiconductor package 16, a heat dissipation pad structure 172 may include heat dissipation pad layers 1721 and heat dissipation via patterns 1723.

The heat dissipation pad layers 1721 may be disposed at different vertical levels to form a multilayer structure. Each of the heat dissipation pad layers 1721 may have a plate shape substantially parallel to the upper surface 129 of the first lower semiconductor device 120. Each of the heat dissipation pad layers 1721 may be positioned at the same vertical level as any one of the second conductive layers 1631. Each of the heat dissipation pad layers 1721 may have the same or similar thickness as the corresponding second conductive layer 1631 positioned at the same vertical level. Among the heat dissipation pad layers 1721, the lowermost heat dissipation pad layer 1721 may extend along the upper surface 129 of the first lower semiconductor device 120 and contact the upper surface 129 of the first lower semiconductor device 120. In example embodiments, the lowermost heat dissipation pad layer 1721 of the heat dissipation pad layers 1721 may entirely cover the upper surface 129 of the first lower semiconductor device 120. The heat dissipation via patterns 1723 may extend in the vertical direction (e.g., the Z direction) through at least one of the plurality of second redistribution insulating layers 161. The heat dissipation via patterns 1723 may connect heat dissipation pad layers 1721 disposed at different vertical levels. A seed metal layer 165 may be disposed on surfaces of the heat dissipation pad layer 1721 and the heat dissipation via patterns 1723. For example, the seed metal layer 165 may extend along the bottom surface of the heat dissipation pad layer 1721 or may extend along sidewalls and bottom surfaces of the heat dissipation via pattern 1723. In example embodiments, the heat dissipation pad structure 172 may be formed together with the second conductive redistribution pattern 163 of the second redistribution structure 160 through the same metal wiring process. In this case, the material and/or material composition of the heat dissipation pad structure 172 may be substantially the same as the material and/or material composition of the second conductive redistribution pattern 163.

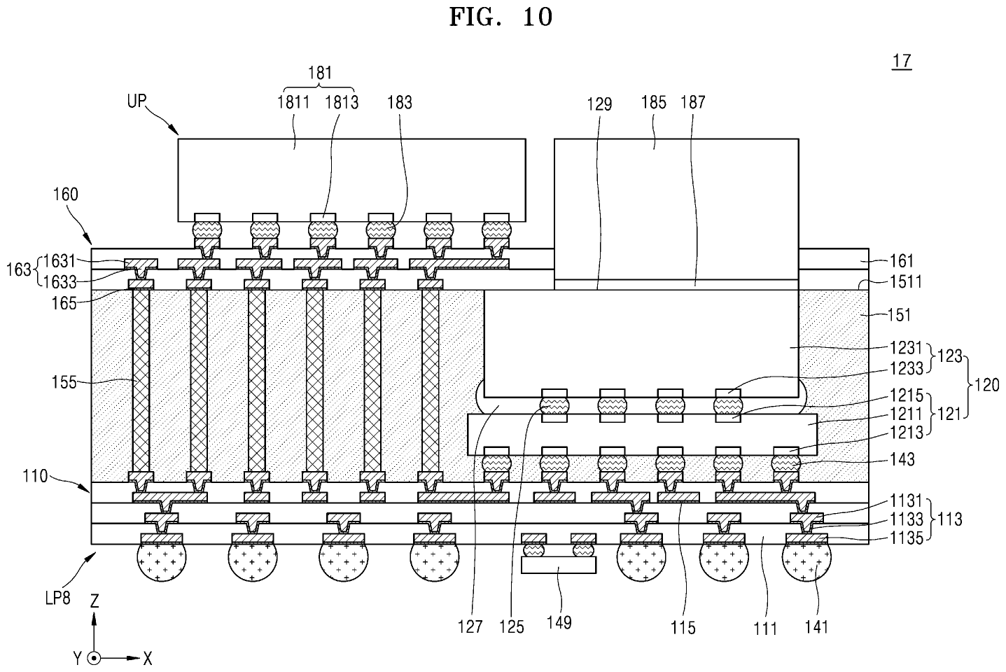

FIG. 10 is a cross-sectional view illustrating a semiconductor package 17 according to embodiments of the inventive concept. Hereinafter, the semiconductor package 17 shown in FIG. 10 will be described focusing on the differences from the semiconductor package 10 described with reference to FIGS. 1 and 2.

Referring to FIG. 10, in the lower package LP8 of the semiconductor package 17, the second redistribution structure 160 may include a through hole penetrating the second redistribution insulating layer 161, and the heat dissipation plate 185 may be accommodated in the through hole of the second redistribution insulating layer 161. The heat dissipation plate 185 may be attached to a portion of the upper surface 129 of the first lower semiconductor device 120 overlapping the through hole of the second redistribution insulating layer 161 through the thermally conductive adhesive layer 187.

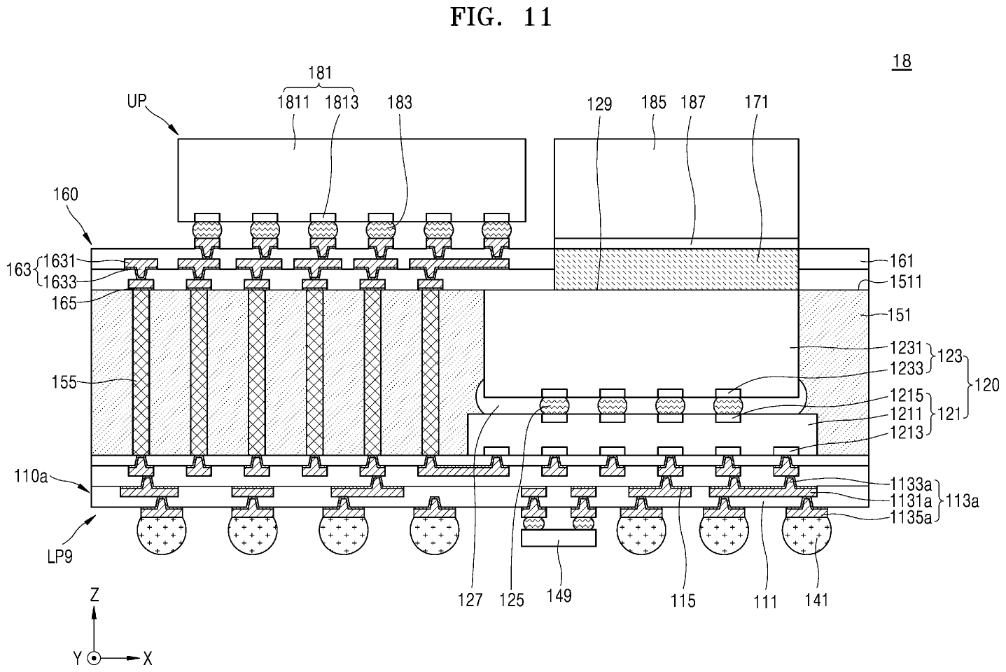

FIG. 11 is a cross-sectional view illustrating a semiconductor package 18 according to embodiments of the inventive concept. Hereinafter, the semiconductor package 18 shown in FIG. 11 will be described focusing on the differences from the semiconductor package 10 described with reference to FIGS. 1 and 2.

Referring to FIG. 11, in the lower package LP9 of the semiconductor package 18, the first lower semiconductor device 120 may be directly connected to the first redistribution structure 110a.

The first conductive redistribution pattern 113a of the first redistribution structure 110a may include first conductive layers 1131a, first conductive via patterns 1133a, and external connection pads 1135a. The first conductive layers 1131a may include line patterns extending along the lower surfaces of each of the plurality of first redistribution insulating layers 111. The first conductive via patterns 1133a may electrically connect first conductive layers 1131a disposed at different vertical levels, or may electrically connect the first conductive layer 1131a and the lower connection pads of the first lower semiconductor device 120. The external connection pad 1135a may protrude downward from the lower surface of the lowermost insulating layer among the plurality of first redistribution insulating layers 111. The external connection pad 1135a may include a portion extending along the lower surface of the lowermost insulating layer among the plurality of first redistribution insulating layers 111 and a portion extending through the lowermost insulating layer. In example embodiments, each of the plurality of first conductive via patterns 1133a may have a tapered shape in which a horizontal width thereof narrows and extends in a direction from a lower side toward an upper side thereof. In other words, the horizontal width of each of the plurality of first conductive via patterns 1133a may gradually decrease as it is closer to the lower connection pad 1213 of the first lower semiconductor device 120.

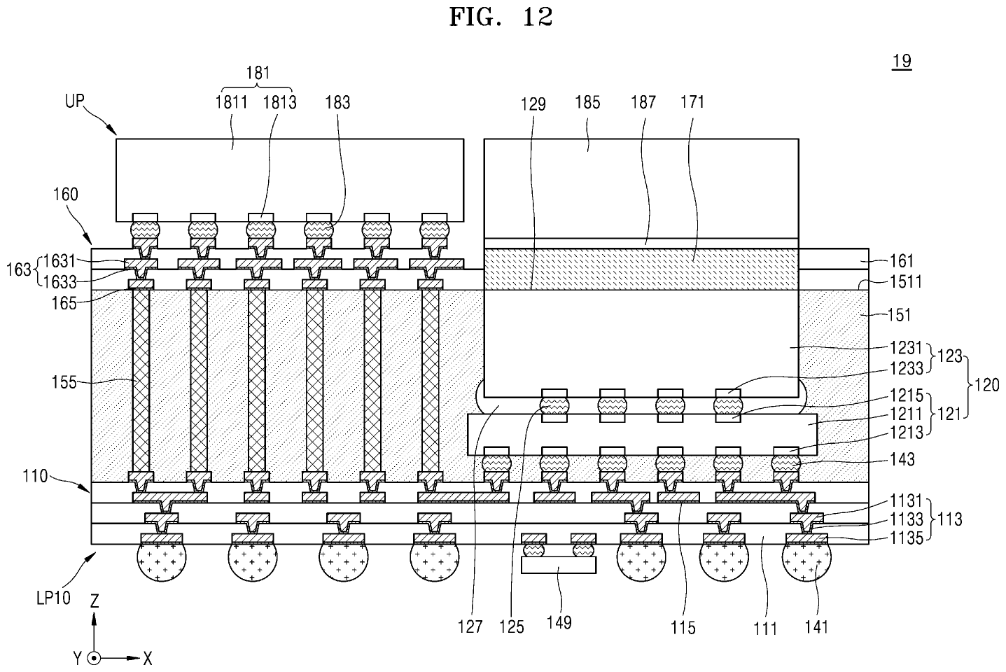

FIG. 12 is a cross-sectional view illustrating a semiconductor package 19 according to embodiments of the inventive concept. Hereinafter, the semiconductor package 19 shown in FIG. 12 will be described focusing on the differences from the semiconductor package 10 described with reference to FIGS. 1 and 2.

Referring to FIG. 12, in the semiconductor package 19, the upper semiconductor device 181 may not vertically overlap the first lower semiconductor device 120. For example, from a plan view, the first lower semiconductor device 120 may be in the first region R1 of FIG. 2 of the first redistribution structure 110, and the upper semiconductor device 181 may be outside the first region R1 of the first redistribution structure 110. In the lower package LP10, the heat dissipation pad structure 171 may extend along the entire upper surface 129 of the first lower semiconductor device 120 and entirely cover the upper surface 129 of the first lower semiconductor device 120.

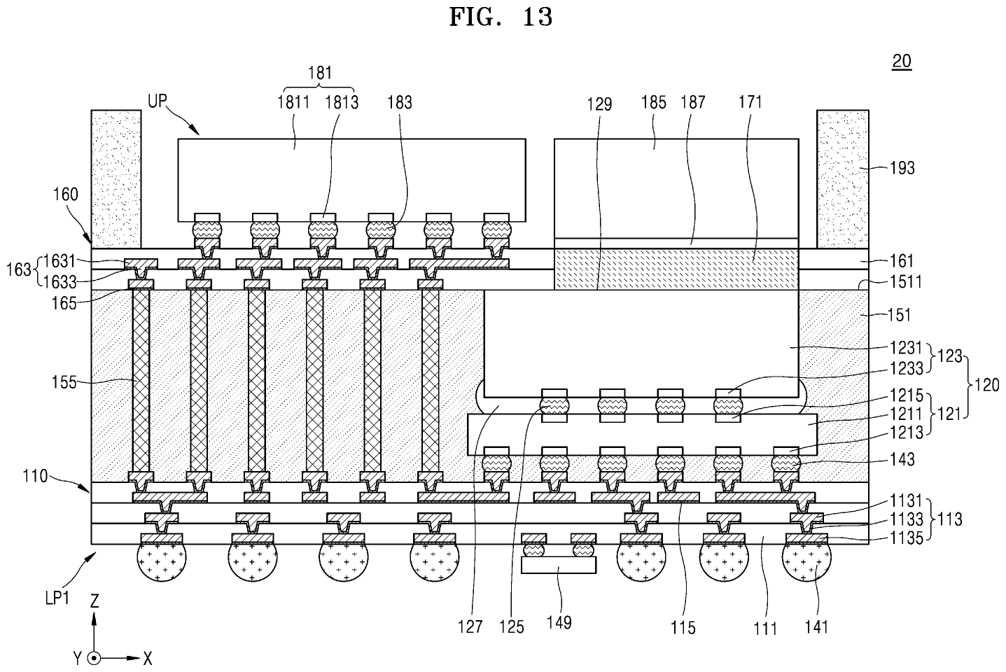

FIG. 13 is a cross-sectional view illustrating a semiconductor package 20 according to embodiments of the inventive concept. Hereinafter, the semiconductor package 20 shown in FIG. 13 will be described focusing on the differences from the semiconductor package 10 described with reference to FIGS. 1 and 2.

Referring to FIG. 13, the semiconductor package 20 may include a stiffener 193 disposed on the lower package LP1. The stiffener 193 may be disposed on the lower package LP1 to overlap the upper semiconductor device 181 and the heat dissipation plate 185 in a lateral direction (e.g., the X direction). The stiffener 193 may be configured to improve mechanical stability of the semiconductor package 20 by mechanically supporting the lower package LP1. For example, as the stiffener 193 mechanically supports the lower package LP1, the stiffener 193 may be configured to alleviate and suppress warpage generated due to differences in thermal expansion coefficients of individual components constituting the semiconductor package 20. The stiffener 193 may include or may be formed of a metal such as steel or copper (Cu). In some embodiments, the stiffener 193, when viewed in a plan view, may surround a region where the heat dissipation plate 185 and the upper semiconductor device 181 are disposed. In some embodiments, an upper surface of the stiffener 193 may be higher than an upper surface of the heat dissipation plate 185 and an upper surface of the upper semiconductor device 181.

For example, the stiffener 193 may be attached on the second redistribution structure 160 through an adhesive material layer. The stiffener 193 may be disposed on the edge region of the second redistribution structure 160. The stiffener 193 may have a ring shape extending along the circumference of the upper surface of the second redistribution structure 160. The stiffener 193 may consist of a single stiffener block or multiple stiffener blocks spaced apart from each other.

While the inventive concept has been particularly shown and described with reference to embodiments thereof, it will be understood that various changes in form and details may be made therein without departing from the spirit and scope of the following claims.

1. A semiconductor package comprising:
a first redistribution structure including a first redistribution insulating layer and a first redistribution pattern;
a first semiconductor device mounted on the first redistribution structure;
a molding layer surrounding the first semiconductor device on the first redistribution structure;
a second redistribution structure disposed on the molding layer and the first semiconductor device and including a second redistribution insulating layer and a second redistribution pattern;
a plurality of vertical connection conductors vertically extending in the molding layer and electrically connecting the first redistribution pattern to the second redistribution pattern;
a second semiconductor device mounted on the second redistribution structure, wherein the second semiconductor device and the first semiconductor device vertically and partially overlap each other;
a heat dissipation pad structure contacting an upper surface of the first semiconductor device; and
a heat dissipation plate disposed on the heat dissipation pad structure and spaced apart from the second semiconductor device along a first straight line extending in a horizontal direction that is parallel to the upper surface of the first semiconductor device.

2. The semiconductor package of claim 1,
wherein the heat dissipation pad structure vertically penetrates the second redistribution insulating layer.

3. The semiconductor package of claim 1,
wherein an upper surface of the molding layer is coplanar with the upper surface of the first semiconductor device.

4. The semiconductor package of claim 1,
wherein a ratio of a first length of a first portion of the first semiconductor device to a total length of the first semiconductor device is a value selected from a range between 10% to 45%,
wherein the first portion of the first semiconductor device vertically overlaps the second semiconductor device, and
wherein the first length of the first portion and the total length are measured in the horizontal direction.

5. The semiconductor package of claim 1, further comprising:
a third semiconductor device mounted on the first redistribution structure and spaced apart from the first semiconductor device along a second straight line extending in the horizontal direction
wherein an entire upper surface of the third semiconductor device vertically overlaps the second semiconductor device.

6. The semiconductor package of claim 5, further comprising:
a plurality of chip connection bumps disposed in a space between the third semiconductor device and the first redistribution structure.

7. The semiconductor package of claim 5,
wherein the second redistribution pattern comprises a conductive via pattern connected to a pad of the third semiconductor device, and
wherein the pad of the third semiconductor device is provided at an upper surface of the third semiconductor device and extends in the molding layer.

8. The semiconductor package of claim 1, further comprising:
a dummy semiconductor substrate disposed on the first redistribution structure and spaced apart from the first semiconductor device along a third straight line extending in the horizontal direction,
wherein the plurality of vertical connection conductors extend vertically in the dummy semiconductor substrate.

9. The semiconductor package of claim 1,
wherein the heat dissipation pad structure comprises:
a plurality of heat dissipation pad layers vertically spaced apart from each other; and
a plurality of heat dissipation vias vertically extending in spaces between two adjacent heat dissipation pad layers of the plurality of heat dissipation pad layers, and
wherein, among the plurality of heat dissipation pad layers, the lowermost heat dissipation pad layer extends along the upper surface of the first semiconductor device.

10. The semiconductor package of claim 1,
wherein the first redistribution pattern comprises:
a first conductive layer disposed within the first redistribution insulating layer;
an external connection pad to which an external connection terminal provided below the first redistribution structure is attached; and
a first conductive via extending in a vertical direction between the first conductive layer and the external connection pad,
wherein the second redistribution pattern comprises:
a second conductive layer disposed within the second redistribution insulating layer; and
a second conductive via extending in the vertical direction from the second conductive layer toward one of the vertical connection conductors,
wherein the first conductive via has a narrowing horizontal width toward the external connection pad, and
wherein the second conductive via has a narrowing horizontal width toward one of the plurality of vertical connection conductors.

11. The semiconductor package of claim 1,
wherein the first redistribution pattern comprises:
a first conductive layer disposed within the first redistribution insulating layer; and
a first conductive via extending vertically between the first conductive layer and a connection pad of the first semiconductor device,
wherein the second redistribution pattern comprises:
a second conductive layer extending in the horizontal direction within the second redistribution insulating layer; and
a second conductive via extending vertically from the second conductive layer towards a corresponding vertical connection conductor of the plurality of vertical connection conductors,
wherein the first conductive via has a narrowing horizontal width toward the connection pad of the first semiconductor device, and
wherein the second conductive via has a narrowing horizontal width toward the corresponding vertical connection conductor.

12. The semiconductor package of claim 1, further comprising a stiffener disposed on the second redistribution structure.

13. The semiconductor package of claim 1,
wherein a thermal conductivity of the heat dissipation plate is greater than a thermal conductivity of silicon.

14. (canceled)

15. A semiconductor package comprising:
a first redistribution structure including a first redistribution insulating layer and a first redistribution pattern;
a first semiconductor device mounted on the first redistribution structure;
a molding layer surrounding the first semiconductor device on the first redistribution structure without covering an upper surface of the first semiconductor device;
a plurality of vertical connection conductors extending vertically in the molding layer and electrically connected to the first redistribution pattern;
a second semiconductor device disposed on the molding layer and electrically connected to the first redistribution pattern through the plurality of vertical connection conductors; and
a heat dissipation plate attached to the upper surface of the first semiconductor device and adjacent to the second semiconductor device along a first straight line extending in a horizontal direction that is parallel to the upper surface of the first semiconductor device.

16. The semiconductor package of claim 15, further comprising:
a plurality of conductive pads disposed on an upper surface of the molding layer and connected to the plurality of vertical connection conductors;
one or more dummy pads disposed on the upper surface of the molding layer and not connected to the plurality of vertical connection conductors; and
a plurality of connection terminals disposed on the plurality of conductive pads and the one or more dummy pads and connected to a plurality of pads of the second semiconductor device.

17. The semiconductor package of claim 15, further comprising
a heat dissipation pad structure disposed between the heat dissipation plate and the upper surface of the first semiconductor device and extending along the upper surface of the first semiconductor device,
wherein the heat dissipation plate is thermally coupled to the first semiconductor device through the heat dissipation pad structure.

18. The semiconductor package of claim 15, further comprising:
a second redistribution structure disposed on the molding layer and the first semiconductor device and including a second redistribution insulating layer and a second redistribution pattern; and
a heat dissipation pad structure disposed between the heat dissipation plate and the upper surface of the first semiconductor device and provided in a through hole of the second redistribution insulating layer.

19. The semiconductor package of claim 15, further comprising:
a second redistribution structure disposed on the molding layer and the first semiconductor device and including a second redistribution insulating layer and a second redistribution pattern;
a plurality of heat dissipation pad layers disposed within the second redistribution insulating layer and vertically spaced apart from each other; and
a plurality of heat dissipation vias disposed in the second redistribution insulating layer and extending vertically in spaces between two adjacent heat dissipation pad layers of the plurality of heat dissipation pad layers,
wherein, among the plurality of heat dissipation pad layers, the lowermost heat dissipation pad layer extends along the upper surface of the first semiconductor device and entirely covers the upper surface of the first semiconductor device.

20. The semiconductor package of claim 15, further comprising:
a third semiconductor device mounted on the first redistribution structure,
wherein a portion of the second semiconductor device vertically overlaps the first semiconductor device, and
wherein another portion of the second semiconductor device vertically overlaps the third semiconductor device.

21-24. (canceled)

25. tor package comprising:
a first redistribution structure including a first redistribution insulating layer and a first redistribution pattern;
a first semiconductor device mounted on the first redistribution structure;
a plurality of chip connection bumps disposed between the first semiconductor device and the first redistribution structure;
a molding layer surrounding the first semiconductor device on the first redistribution structure and having an upper surface that is coplanar with an upper surface of the first semiconductor device;
a second redistribution structure disposed on the molding layer and the first semiconductor device and including a second redistribution insulating layer and a second redistribution pattern;
a plurality of vertical connection conductors vertically penetrating the molding layer and electrically connecting the first redistribution pattern to the second redistribution pattern;
a second semiconductor device mounted on the second redistribution structure;
a heat dissipation pad structure disposed within the second redistribution insulating layer and contacting the upper surface of the first semiconductor device; and
a heat dissipation plate disposed on the heat dissipation pad structure and spaced apart from the second semiconductor device along a straight line extending in horizontal direction that is parallel to the upper surface of the first semiconductor device,
wherein the first semiconductor device comprises a logic chip,
wherein the second semiconductor device comprises a memory chip,
wherein the heat dissipation plate is thermally coupled to the first semiconductor device through the heat dissipation pad structure,
wherein a first portion of the first semiconductor device vertically overlaps the second semiconductor device,
wherein a second portion of the first semiconductor device vertically overlaps the heat dissipation plate,
wherein a ratio between a first length of the first portion of the first semiconductor device to a total length of the first semiconductor device is selected from a range between 10% to 45%, and
wherein the first length and the total length are measured in the horizontal direction.
